(19) United States
(12) Patent Application Publication
(10) Pub. No.: US 2025/0362336 A1
(43) Pub. Date: Nov. 27, 2025

(54) METHOD AND SYSTEM FOR FAULT DETECTION AND PREDICTION IN ELECTRIC GRIDS

(71) Applicant: Safegrid Oy, Espoo (FI)

(72) Inventors: Tapio Mäntysalo, Hevonpää (FI); Ville Peltoniemi, Piikkiö (FI)

(73) Assignee: Safegrid Oy, Espoo (FI)

(21) Appl. No.: 19/217,026

(22) Filed: May 23, 2025

(30) Foreign Application Priority Data
May 24, 2024 (FI) 20245668

(51) Int. Cl. G01R 31/28; G01R 31/08

(52) U.S. Cl. CPC G01R 31/2841; G01R 31/083; G01R 31/085

(57) ABSTRACT

A method for detecting high-frequency traveling waves in an electrical system by use of current sensors, the method including arranging association of at least one current detection sensor with at least one conductor in the electrical system, where the at least one conductor is associated with at least one parasitic capacitance; receiving at least one measurement from the at least one current detection sensor, where the at least one measurement is based on flow of stray current through the at least one parasitic capacitance; and detecting, based on the at least one measurement, a traveling wave that corresponds to the stray current, where the flow of the stray current through the at least one parasitic capacitance is based on propagation of the traveling wave through the at least one conductor. Disclosed is also an arrangement for detecting high-frequency traveling waves in an electrical system.

### TECHNICAL FIELD

The present disclosure relates to traveling wave detection in electrical systems for detection and prevention of faults in the electrical systems. In particular, the present disclosure relates to a method and an arrangement for detecting high-frequency traveling waves in electrical systems using current sensors.

### BACKGROUND

Traveling waves propagate in an electric system (such as a power line or a conductor in an electric grid) in various forms (voltage signals or current signals) due to a variety of factors. Primarily, the propagation is due to a presence of a fault or a possibility of occurrence of a fault in the electric grid. The traveling waves may propagate at a velocity that is close to the velocity of light and their detection may indicate the condition of the electric grid. After detection of the traveling waves, an analysis of the traveling waves may be performed. The detection and analysis of the traveling waves ensure (or enhance) reliability, efficiency, and safety of the electric grid. In an example, traveling waves, propagating in a distribution line, may be detected. Based on the detection it is determined that the propagation of the traveling wave is due to faults such as a short circuit or a lightning strike. Additionally, traveling waves, detected in the electric grid, may be indicative of occurrence of transient events in a portion of the electric grid. After the detection, appropriate measures may be introduced to fix issues that may arise due to the faults and/or the transient events.

The detection of traveling waves in electrical systems may be critical in power systems or high-voltage installations. This is because detection of the traveling waves allows determination of precise location where a fault (such as equipment failure) has occurred or where there is a likelihood of occurrence of faults, detection of abnormalities indicative of impending faults or insulation breakdowns, and so on. The determination may allow fixing issues that may have caused the fault or may lead to the occurrence of the fault, and proactive adoption of maintenance measures. Traveling wave detection may, thus, function as an early warning system that facilitates prediction of potential equipment failures or deteriorating conditions within the electrical systems. Fixing the issues minimizes potential downtime and increases the reliability of the electrical systems.

The detection of the traveling waves further allows coordinating protection relays that may be used for isolating sections of the electric grid where a fault has been detected such that equipment in other sections of the electric grid are protected from damage. The coordination involves activation of the protective relays and prevention of unnecessary power outages that may be caused due to equipment damage. Furthermore, analysis of distinct characteristics (such as amplitude, frequency, velocity, and so on) of detected traveling waves enable differentiating diverse types of faults that have occurred or are likely to occur. This may be because the presence of faults associated with a certain category may lead to the detection of traveling waves of a certain amplitude, frequency, velocity and so on. Therefore, based on one or more parameters of the detected traveling waves, type and severity of faults may be identified, a rapid and accurate fault diagnosis may be facilitated, and restoration procedures may be initiated.

However, there are challenges involved in the detection of traveling waves. The traveling waves may be of low amplitude and/or frequency, which may hinder their detection or reduce accuracy of detection. This is because traveling waves may experience distortion during propagation, leading to changes in waveform shape, amplitude, frequency, and so on. Factors such as impedance variations, line terminations, and reflections may contribute to the distortion, which enhances the challenges involved in accurately detecting and analyzing the traveling waves. In scenarios where a traveling wave is propagating via a path that terminates at an open switch or a high-impedance device, the traveling wave is blocked. This prevents detection and measurement of the traveling waves.

Therefore, considering the foregoing discussion, there exists a need to overcome the aforementioned drawbacks.

### SUMMARY

The aim of the present disclosure is to provide a method for detecting high-frequency traveling waves by use of current sensors. The method allows arranging current detection sensors around conductors through which traveling waves are likely to propagate if there is a presence of a fault, a transient event, a deteriorating situation, and so on. The method is operable to leverage stray or parasitic capacitances, associated with various components (such as secondary transformers, switches, cables, current arrestors, and so on) connected to the conductors. The stray capacitances provide a passage for flow of stray currents, corresponding to the high-frequency traveling waves, through the components. The sensors, arranged around the conductors, may detect the flow of stray current, and, based on measurements received from the current sensors, the traveling waves may be detected. The aim of the present disclosure is achieved by the provided method and an electrical system for detection of high-frequency traveling waves by use of current sensors as defined in the appended independent claims to which reference is made to.

The aim of the present disclosure is also to provide an arrangement for detecting high-frequency traveling waves in an electrical system by use of current sensors.

Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers, or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 illustrates an exemplary arrangement for detecting traveling waves by leveraging a stray capacitance associated with a switch included in an electrical system, in accordance with an embodiment of the present disclosure;

FIG. 2 illustrates an exemplary arrangement for detecting traveling waves by leveraging a stray capacitance associated with a surge voltage arrestor included in an electrical system, according to an embodiment of the present disclosure;

FIG. 3 illustrates an exemplary arrangement for detecting traveling waves by leveraging stray capacitances associated with a transformer included in an electrical system, according to an embodiment of the present disclosure;

FIG. 4 illustrates an exemplary arrangement for detecting traveling waves by leveraging stray capacitances associated with cable taps from a power line included in an electrical system, according to an embodiment of the present disclosure;

FIG. 5 illustrates an exemplary arrangement for detecting traveling waves by leveraging stray capacitances associated with an underground cable included in an electrical system, according to an embodiment of the present disclosure;

FIG. 6 illustrates an exemplary arrangement for detecting traveling waves by leveraging stray capacitances associated with a set of surge voltage arrestors included in an electrical system, according to an embodiment of the present disclosure;

FIG. 7 illustrates an exemplary arrangement for detecting traveling waves by leveraging stray capacitances associated with overhead power lines, switches, a surge voltage arrestor, and a transformer included in an electrical system, in accordance with an embodiment of the present disclosure;

FIG. 8 depicts steps of a method for detecting high-frequency traveling waves by use of current sensors in electrical systems, in accordance with an embodiment of the present disclosure;

FIG. 9A illustrates an exemplary arrangement for detecting traveling waves from ground wires by use of a set of Rogowski coils or current transformers included in an electrical system, in accordance with an embodiment of the present disclosure;

FIG. 9B illustrates another exemplary arrangement for detecting traveling waves from ground wires in accordance with an embodiment of the present disclosure;

FIG. 9C illustrates yet another exemplary arrangement for detecting traveling waves from ground wires in accordance with an embodiment of the present disclosure; and

FIG. 10 illustrates another exemplary arrangement for detecting traveling waves by use of a set of Rogowski coils or current transformers included in an electrical system, in accordance with an embodiment of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

In a first aspect, the present disclosure provides a method for detecting traveling waves in an electrical system, the method comprising:
arranging association of at least one current detection sensor with at least one conductor in the electrical system, wherein the at least one conductor is associated with at least one parasitic capacitance;
receiving at least one measurement from the at least one current detection sensor, wherein the at least one measurement is based on flow of a stray current through the at least one parasitic capacitance; and
detecting, based on the at least one measurement, a traveling wave that corresponds to the stray current, wherein the flow of the stray current through the at least one parasitic capacitance is based on propagation of the traveling wave through the at least one conductor.

In a second aspect, the present disclosure provides an arrangement for detecting traveling waves in an electrical system, the arrangement comprising:
at least one current detection sensor;
wherein the at least one current detection sensor is configured to be associated with at least one conductor, wherein the at least one conductor is associated with at least one parasitic capacitance; and
a processor, wherein the processor is operable to:
   receive at least one measurement from the at least one current detection sensor, wherein the at least one measurement is based on flow of a stray current through the at least one parasitic capacitance, and
   detect, based on the at least one measurement, a traveling wave that corresponds to the stray current, wherein the flow of the stray current through the at least one parasitic capacitance is based on propagation of the traveling wave through the at least one conductor.

The present disclosure provides the aforementioned first aspect and the aforementioned second aspect to facilitate detection of high-frequency traveling waves propagating in power lines, such as transmission lines or distribution lines, of an electrical system. The high-frequency traveling waves are detected by measuring stray electric currents corresponding to the traveling waves. The stray currents may be measured by leveraging stray capacitances that are associated with conductors through which the traveling waves may propagate. The association of the conductors with the stray capacitances is due to components of the electrical system that are connected to the conductors. The conductors connect the components with ground terminals of the electrical system. The stray capacitances belong to the components of the electrical system and provide low-impedance paths that facilitate the flow of stray currents to the ground terminals. The conductors are associated with current detection sensors that are operable to measure the stray currents flowing through the conductors. The measurements of the current detection sensors enable detection of traveling waves propagating in the electrical system. The current detection sensors can be installed on shielded cables, neutral and grounding wires without power outage, and without a galvanic connection with the conductors (such as distribution or transmission lines).

The availability of the low-impedance paths, facilitated by the leveraging of the stray capacitances of the components of the electrical system, prevents distortion and/or attenuation of the traveling waves as they propagate through the conductors. The lack of distortion/attenuation may lead to obtaining accurate measurements of characteristic features of the traveling waves and, subsequently, accurately detecting faults and/or transient events in the electrical system. Furthermore, the traveling waves propagating through the conductors may be enhanced to prevent random detections of traveling waves. The detections may be random in some configurations where the conductors are connected to high-impedance components. In some scenarios, amplitude of the traveling waves may be sufficient enough for the traveling wave to pass through the high-impedance components via stray capacitances of the high-impedance components. In some other scenarios, distorted/attenuated traveling waves may not be able to pass through the high-impedance components. Thus, random detections may be prevented by enhancing stray currents flowing through the conductors, prior to flows of the stray currents reaching the high-impedance components.

For detection of the high-frequency traveling waves, the at least one current detection sensor is employed. The at least one current detection sensor is associated with the at least one conductor in the electrical system. The at least one conductor may be connected to at least one electrical component of the electrical system. In an embodiment, the at least one conductor may correspond to at least one overhead power line. The at least one overhead power line may include a set of segments that are associated with at least one electrical component. Optionally, the electrical system is a primary substation or a secondary substation (i.e., portions of an electric grid). The electrical system may include a set of electrical components. The set of electrical components may include at least one switch, at least one surge voltage arrestor, at least one transformer, at least one underground cable, and at least one overhead power line. In an embodiment, the set of segments of the at least one overhead power line is connected by the at least one switch. Each switch may connect a pair of segments of the set of segments constituting each overhead power line.

In another embodiment, the at least one conductor may correspond to at least one cable tap from a power line. The at least one cable tap may be connecting the power line to at least one electrical component of the set of electrical components. The at least one electrical component may include the at least one switch and the at least one transformer. In another embodiment, the at least one conductor may be at least one electrical wire that connects at least one electrical component of the set of electrical components with at least one ground terminal of the electrical system. The at least one electrical component may be the at least one surge voltage arrestor or the at least one transformer.

In another embodiment, the at least one conductor may correspond to at least one electrical wire that connects at least one electrical component of the set of electrical components with at least one ground terminal of the electrical system via at least one metallic shield or at least one electric shield. The at least one electrical component may be enclosed by the at least one metallic shield or the at least one electric shield. The at least one electrical component may be the at least one underground cable that is enclosed by the at least one metallic shield or the at least one overhead power line that is enclosed by the at least one electric shield.

The at least one current detection sensor, whose association with the at least one conductor is arranged, is operable to measure electric current that may be flowing through the at least one conductor. The electric current flowing through the at least one conductor may be a stray or parasitic current. The stray current corresponds to a traveling wave which may be propagating through the at least one conductor due to one or more factors (such as presence of at least one fault or occurrence of at least one transient event in the electrical system). Optionally, a frequency of the traveling wave is in the range 10 Kilohertz (kHz)-4 Gigahertz (GHz). The flow of the stray current through the at least one conductor is based on the association of the at least one conductor with the at least one parasitic capacitance. The association of the at least one conductor with the at least one parasitic capacitance may be due to at least one electrical component of the set of electrical components. This may be because the at least one parasitic capacitance belongs to the at least one electrical component to which the at least one conductor is connected. The at least one parasitic capacitance of the at least one electrical component may provide a low-impedance path via which stray currents, i.e., the traveling waves, propagate to at least one ground terminal of the electrical system.

In an embodiment, the stray current flows through the at least one overhead power line (i.e., the at least one conductor). The flow of the stray current may be due to the at least one parasitic capacitance associated with the at least one overhead power line (as the at least one parasitic capacitance provides a path to the stray current to flow). The at least one parasitic capacitance may belong to the at least one switch that connects the set of segments of the at least one overhead power line. The at least one current detection sensor, associated with the at least one overhead power line, measures the stray current.

In another embodiment, a portion of the stray current flows through the power line and at least one portion of the stray current flows through the at least one cable tap. A significant portion of energy of the traveling wave may propagate through the at least one cable tap (i.e., the at least one conductor) and a minuscule portion of the energy of the traveling wave may continue to propagate through the power line. The flow of the stray current from the overhead power line to the at least one cable tap may be due to the at least one parasitic capacitance associated with the at least one electrical component of the set of electrical components (to which the overhead power line may be connected via the at least one cable tap). The at least one electrical component may include at least one switch and at least one transformer. The at least one parasitic capacitance may belong to the at least one electrical component (i.e., the at least one switch and at least one transformer). The at least one parasitic capacitance provides a low-impedance path for the stray current to flow from the overhead power line to the at least one electrical component via the at least one cable tap. The at least one current detection sensor, associated with the at least one cable tap, measures the stray current flowing through the at least one cable tap.

In another embodiment, the stray current flows through the at least one electrical wire. The flow of the stray current may be due to the at least one parasitic capacitance associated with the at least one electrical wire (i.e., the at least one conductor). The at least one parasitic capacitance belongs to the at least one electrical component of the set of electrical components connected to the at least one ground terminal via the at least one electrical wire. The at least one parasitic capacitance provides at least one low-impedance path that allows the stray current to flow from the at least one electrical component (the at least one surge voltage arrestor or the at least one transformer) to the at least ground terminal via the at least one electrical wire. The at least one current detection sensor, associated with the at least one electrical wire, may measure the stray current flowing through the at least one electrical wire.

In another embodiment, the stray current flows through the at least one electrical wire (i.e., the at least one conductor). The flow of the stray current may be due to the at least one parasitic capacitance associated with the at least one electrical wire. The at least one parasitic capacitance belongs to the at least one underground cable or the at least one overhead power line connected to at least one electrical wire. The stray current flows from the at least one underground cable or the at least one overhead power line to the at least one metallic/electric shield that surrounds the at least one underground cable or the at least one overhead power line via the at least one parasitic capacitance. Thereafter, the stray current flows to the at least one ground terminals via the at least one electrical wire. The at least one parasitic capacitance provides at least one low-impedance path for the stray current to flow from the at least one underground cable/overhead power line to the at least one metallic/electric shield and, subsequently, the at least one ground terminal via the at least one electrical wire. The at least one current detection sensor, which is associated with the electrical wire, measures the stray current.

The at least one current detection sensor may generate at least one measurement by measuring the stray current flowing through the at least one conductor. The at least one current detection sensor may transmit the at least one measurement, which is received for analysis. The at least one measurement is based on the flow of the stray current through the at least one parasitic capacitance. Thus, the stray current, indicative of propagation of the traveling wave through the at least one conductor may be measured by leveraging the at least one parasitic capacitance belonging to the at least one electric component connected to the at least one conductor. Based on the at least one measurement, the traveling wave, that corresponds to the stray current, is detected to be propagating through the at least one conductor.

The association of the at least one current detection sensor with the at least one conductor may be arranged by various means. Optionally, the at least one current detection sensor may be associated with the at least one conductor by wrapping the at least one current detection sensor around at least one ending terminal of at least one electric shield. The at least one electric shield may enclose the at least one conductor. The at least one conductor corresponds to the at least one overhead power line that includes the set of segments. A pair of segments of the set of segments, included in an overhead power line, may be connected to each other by an electric component of the set of electrical components.

A segment of the pair of segments may be enclosed by an electric shield. Furthermore, a current detection sensor may be wrapped around an ending terminal of the electric shield. The electric component connecting the pair of segments may be a switch that includes two terminals. Optionally, the at least one switch connects the set of segments of the at least one conductor (i.e., the at least one overhead power line). The terminals of the at least one switch may be connected to each other by the at least one parasitic capacitance when the at least one switch is in an open state. The at least one overhead power line may be associated with the at least one parasitic capacitance. The at least one parasitic capacitance belongs to the at least one switch and provides at least one path for the stray current to flow through the at least one overhead power line when the at least one switch is in the open state. The propagation of a traveling wave through the at least one overhead power line is detected based on the at least one measurement (performed by the at least one current detection sensor) of the stray current flowing through the at least one parasitic capacitance (the at least one switch in the open state).

Optionally, the at least one current detection sensor is associated with the at least one conductor by wrapping the at least one current detection sensor around at least one ending terminal of the at least one conductor. The at least one conductor may connect at least one electrical component of the set of electrical components with at least one ground terminal of the electric system. The at least one electrical component corresponds to the at least one the surge voltage arrestor or the at least one transformer. The at least one conductor may correspond to the at least one electrical wire around which the at least one current detection sensor is wrapped. The at least one electrical wire may be associated with at least one parasitic capacitance that belongs to the at least one the surge voltage arrestor or the at least one transformer.

Optionally, the at least one surge voltage arrestor includes the at least one parasitic capacitance. Thus, the at least one surge voltage arrestor (i.e., the at least one parasitic capacitance) may provide at least one path for the stray current to flow to the at least one ground terminal via the at least one electrical wire. Optionally, the at least one transformer may include a core and a pair of windings. The at least one transformer is housed in at least one container. The pair of windings of the at least one transformer may be connected to each other by at least one parasitic capacitance. The core and the container of the at least one transformer may be connected by at least one parasitic capacitance. It should be noted that the at least one transformer connecting the pair of windings is different from the at least one parasitic capacitance connecting the core and the container. Thus, the at least one transformer (i.e., the at least one parasitic capacitance) may provide at least one path for the stray current to flow to the at least one ground terminal via the at least one electrical wire. The propagation of a traveling wave through the at least one surge voltage arrestor/the at least one transformer may be detected based on the at least one measurement (performed by the at least one current detection sensor) of the stray current flowing through the at least one parasitic capacitance (i.e., the at least one surge voltage arrestor or the at least one transformer) to the at least one ground terminal.

The at least one transformer may include a high-voltage section and a low-voltage section that are associated with the pair of windings included in the at least one transformer. The pair of windings include a primary winding that is associated with the high-voltage section and a secondary winding that is associated with the low-voltage section. For an accurate estimation of the stray current, corresponding to a traveling wave, it may be necessary that the stray current flowing through the at least one electrical wire (and measured by the at least one current detection sensor) does not include electric current that flows through the at least one parasitic capacitance connecting the pair of windings (i.e., the primary and secondary windings) of the at least one transformer. This is because the electric current contributes to noise.

Optionally, the flow of the electric current from the secondary winding of the at least one transformer to the at least one conductor via the at least one parasitic capacitance (connecting the pair of windings) is prevented. If the flow is not prevented, then the electric current flows from the secondary winding (i.e., the low-voltage section) to the primary winding (i.e., the high-voltage section) via the at least one parasitic capacitance and gets included in the at least one measurement of the at least one current detection sensor wrapped around the at least one electrical wire (that connects the at least one transformer to the at least one ground terminal). This can contribute to noise. The prevention of the flow of the electric current improves accuracy of the at least one measurement and, simultaneously, accuracy of detection of the traveling wave.

Optionally, the at least one current detection sensor is associated with the at least one conductor by wrapping the at least one current detection sensor around at least one ending terminal of the at least one conductor.

The at least one conductor connects the power line with one or more of the at least one transformer and the at least one switch. The at least one conductor may correspond to at least one cable tap, originating from the power line and connecting the power line to one or more of the at least one transformer and the at least one switch. The at least one cable tap is associated with the at least one parasitic capacitance. The association is due to inclusion of the at least one parasitic capacitance in one or more of the at least one transformer and the at least one switch. The flow of stray current via the at least one cable tap is due to the at least one capacitance. The propagation of a traveling wave through the at least one cable tap may be detected based on the at least one measurement (performed by the at least one current detection sensor) of the stray current flowing through the at least one parasitic capacitance (belonging to the at least one transformer and the at least one switch).

Optionally, a current signal is enhanced for generating an enhanced current signal. The enhanced current signal corresponds to the stray current flowing to one or more of the at least one transformer and the at least one switch, via the at least one cable tap. An amplitude of the stray current is greater than or equal to a threshold amplitude that is detectable by the at least one detection sensor. This is because of the enhancement of the current signal. The current signal may be required to be enhanced, as a portion (however minuscule) of the stray current may continue to flow through the power line and only a certain portion of the stray current, i.e., the current signal, flows to one or more of the at least one transformer and the at least one switch via the at least one cable tap.

The enhancement of the current signal ensures that the amplitude of the stray current, i.e., the enhanced current signal, is greater than the threshold amplitude, and the traveling wave is accurately detected. Optionally, the current signal is enhanced based on an arrangement causing a superposition of an electric current flowing through the power line and the current signal.

Optionally, the at least one current detection sensor is associated with the at least one conductor by wrapping the at least one current detection sensor around at least one ending terminal of the at least conductor. The at least one conductor may correspond to at least one electrical wire. The at least one conductor (i.e., the at least one electrical wire) connects the at least one underground cable (i.e., an electrical component of the set of electric components) with at least one ground terminal of the electric system via the at least one metallic shield enclosing the at least one underground cable. The at least one electrical wire is associated with at least one parasitic capacitance belonging to the at least one underground cable. Optionally, the at least one underground cable and the at least one metallic shield are connected by the at least one parasitic capacitance.

The at least one parasitic capacitance may provide at least one low-impedance path for the stray current (corresponding to a traveling wave) to flow (propagate) from the at least one underground cable to the at least one metallic shield. Subsequently the stray current flows to the at least one ground terminal via the at least one electrical wire. The propagation of a traveling wave through the at least one underground cable may be detected based on the at least one measurement (performed by the at least one current detection sensor) of the stray current flowing through the at least one electrical wire.

Optionally, the at least one current detection sensor is associated with the at least one conductor by wrapping the at least one current detection sensor around at least one ending terminal of the at least conductor. The at least one conductor may correspond to at least one electrical wire. The at least one conductor (i.e., the at least one electrical wire) connects the at least one overhead power line (i.e., an electrical component of the set of electric components) with at least one ground terminal of the electric system via the at least one electric shield enclosing the at least one overhead power line. The at least one electrical wire is associated with at least one parasitic capacitance that belongs to the at least one overhead power line. Optionally, the at least one overhead power line and the at least one electric shield are connected by the at least one parasitic capacitance. The at least one parasitic capacitance may provide at least one path for a first portion of the stray current (corresponding to a traveling wave) to flow (propagate) from the at least one overhead power line to the at least one electric shield and, subsequently, the at least one ground terminal via the at least one electrical wire.

The at least one overhead power line includes a set of segments. Each overhead power line includes two segments of the set of segments. One of the segments is enclosed by an electric shield. The two segments may be connected to each other by a switch that includes two terminals. Optionally, the at least one switch connects the set of segments of the at least one overhead power line. The terminals of the at least one switch are connected by the at least one parasitic capacitance when the at least one switch is in an open state. Thus, the terminals of each switch connect the two segments of each overhead power line. The at least one overhead power line is associated with the at least one parasitic capacitance that belongs to the at least one switch. The at least one parasitic capacitance provides at least one path for a second portion of the stray current to flow through the at least one overhead power line when the at least one switch is in the open state. The second portion of the stray current refers to a portion of the stray current that continues to flow through the at least one overhead power line after the first portion of the stray current flows to the at least one ground terminal via the at least one electrical wire.

Furthermore, the at least one conductor (i.e., the at least one electrical wire) connects the at least one overhead power line to at least one ground terminal via at least one surge voltage arrestor (i.e., an electrical component of the set of electrical components). The at least one current detection sensor is associated with the at least one electrical wire for obtaining the at least one measurement of a third portion of the stray current flowing through the at least one electrical wire. The third portion of the stray current is a portion of the second portion of the stray current.

The at least one electrical wire is associated with the at least one parasitic capacitance belonging to the at least one surge voltage arrestor. The at least one parasitic capacitance belonging to the at least one surge voltage arrestor provides at least one path for the third portion of the stray current to flow to the at least one ground terminal. The propagation of a traveling wave through the at least one overhead power line may be detected based on the at least one measurement (performed by the at least one current detection sensor) of the first portion of the stray current and the third portion of the stray current flowing through the at least one electrical wire.

The present disclosure also relates to the second aspect as described above. Various embodiments and variants disclosed above, with respect to the aforementioned first aspect, apply mutatis mutandis to the second aspect.

An arrangement for an electrical system for detecting traveling waves comprises at least one current detection sensor, wherein the at least one current detection sensor is configured to be associated with at least one conductor, wherein the at least one conductor is associated with at least one parasitic capacitance. The arrangement further comprises a processor. The at least one current detection sensor is configured to measure a stray current flowing through the at least one conductor. The at least one conductor may be connected to at least one electrical component and associated with at least one parasitic capacitance. The association of the at least one conductor with the at least one parasitic capacitance is due to the connection as the at least one parasitic capacitance belongs to the at least one electrical component. The at least one parasitic capacitance provides at least one low-impedance path that enables the stray current to flow through the at least one conductor. In operation, when the at least one current detection sensor is associated with said at least one conductor, the at least one current detection sensor may measure the stray current flowing through the at least one conductor. Thereafter, the at least one current detection sensor may transmit at least one measurement of stray current, flowing through the at least one conductor, to the processor. Based on said measurement, the processor is capable of detecting (i.e., the processor detects) whether a traveling wave is propagating through the at least one conductor or the at least one electrical component.

In general, inclusion of additional current detection sensors may facilitate detection of high-frequency traveling wave signals, which may propagate to ground terminals through paths created by the stray capacitances of the electrical system. The stray capacitances enhance the sensitivity of the arrangement, in the electrical system, to the high-frequency traveling wave signals. In an embodiment, all current detection sensors of the arrangement may be required to be installed in the same direction. Such installation may maximize the probability of all high-frequency traveling wave signals, detected by the current detection sensor (situated at the ends of the conductors), having the same polarity. This may facilitate in obtaining a summation of the high-frequency traveling wave signals prior to their detection (which results in an accurate detection).

### DETAILED DESCRIPTION OF THE DRAWINGS

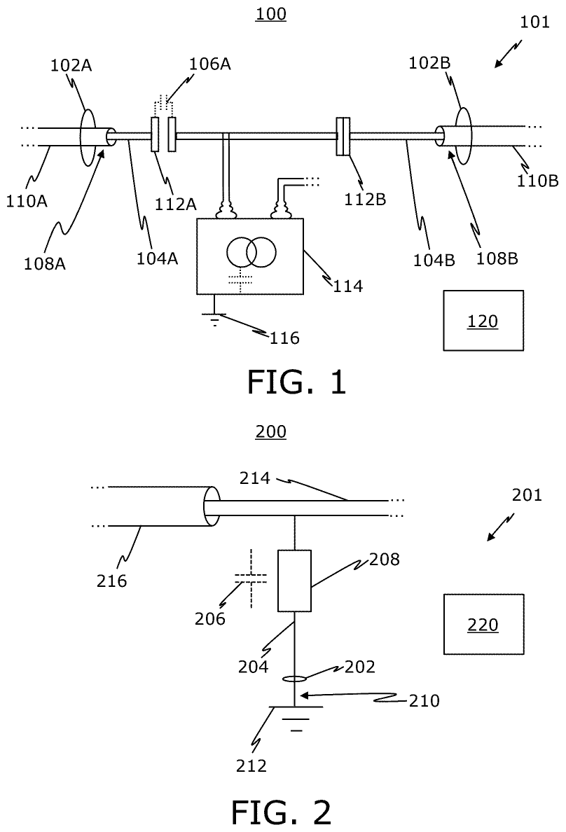

Referring to FIG. 1, there is illustrated an exemplary arrangement for detecting traveling waves by leveraging a stray capacitance associated with a switch included in an electrical system 100, in accordance with an embodiment of the present disclosure. The electrical system 100 may be a primary substation or a secondary substation. The electrical system 100 has a first conductor 104A (a first overhead power line), and a second conductor 104B (a second overhead power line). The arrangement 101 for detecting traveling waves in the electrical system 100 comprises a first current detection sensor 102A, a second current detection sensor 102B, and a processor 120. The first conductor 104A is associated with the first current detection sensor 102A and a first parasitic capacitance 106A. The second conductor 104B is associated with the second current detection sensor 102B. The association of the first current detection sensor 102A with the first conductor 104A is arranged based on wrapping of the first current detection sensor 102A around a first ending terminal 108A of a first electric shield 110A that encloses the first conductor 104A. The association of the second current detection sensor 102B with the second conductor 104B is arranged based on wrapping of the second current detection sensor 102B around a second ending terminal 108B of a second electric shield 110B that encloses the second conductor 104B. The electrical system 100 may further include electrical components, viz., a first switch 112A and a second switch 112B. Each of the first conductor 104A and the second conductor 104B includes two segments. The first switch 112A connects the segments of the first conductor 104A and the second switch 112B connects the segments of the second conductor 104B. Each of the first switch 112A and the second switch 112B include two terminals. The terminals of the first switch 112A are connected by the first parasitic capacitance 106A when the first switch 112A is in open state. The association of the first conductor 104A with the first parasitic capacitance 106A is based on the connections of the segments of the first conductor 104A with the terminals of the first switch 112A.

The first current detection sensor 102A measures stray current flowing through the first conductor 104A. The flow of the stray current may be due to propagation of a traveling wave through the first conductor 104A. The first parasitic capacitance 106A of the first switch 112A provides a low-impedance path for the stray current to flow through the first conductor 104A. Based on the measurement of the stray current by the first current detection sensor 102A, the presence of the traveling wave in the first conductor 104A is detected. Additionally, the electrical system 100 may include a transformer 114 that includes a parasitic capacitance and is connected to a ground terminal 116.

FIG. 1 is merely an example, which should not unduly limit the scope of the claims herein. A person skilled in the art will recognize many variations, alternatives, and modifications of embodiments of the present disclosure. For example, the arrangement can include any number of current detection sensors. Furthermore, the electrical system can include other types of conductors (apart from overhead power lines) and electrical components (apart from switches).

Referring to FIG. 2, there is illustrated an exemplary arrangement for detecting traveling waves by leveraging a stray capacitance associated with a surge voltage arrestor included in an electrical system 200, in accordance with an embodiment of the present disclosure. The electrical system 200 includes a conductor 204 (an electrical wire), e.g., a ground wire. The conductor 204 is associated with a parasitic capacitance 206. The electrical system 200 further includes a surge voltage arrestor 208 (an electrical component). The surge voltage arrestor 208 includes the parasitic capacitance 206. Referring further to FIG. 2, the arrangement 201 for detecting traveling waves in the electrical system 200 comprises a current detection sensor 202, wherein the current detection sensor is associated with said conductor 204, and a processor 220, wherein the processor is associated with the current detection sensor 202. The association of the current detection sensor 202 with the conductor 204 may be arranged based on wrapping of the current detection sensor 202 around an ending terminal 210 of the conductor 204. The conductor 204 connects the surge voltage arrestor 208 with a ground terminal 212 of the electrical system 200. The association of the conductor 204 with the parasitic capacitance 206 may be based on the connection of the conductor 204 with the surge voltage arrestor 208.

The current detection sensor 202 measures stray current flowing through the conductor 204. The flow of the stray current may be due to propagation of a traveling wave through a conductor 214 enclosed by an electric shield 216. The parasitic capacitance 206 of the surge voltage arrestor 208 provides a low-impedance path for the stray current to flow from the conductor 214 to the ground terminal 212 via the conductor 204 (i.e., the surge voltage arrestor 208). Based on the measurement of the stray current by the current detection sensor 202, a presence of the traveling wave in the conductor 214 and the conductor 204 (and the surge voltage arrestor 208) is detected.

FIG. 2 is merely an example, which should not unduly limit the scope of the claims herein. A person skilled in the art will recognize many variations, alternatives, and modifications of embodiments of the present disclosure. For example, the arrangement can include any number of current detection sensors. Furthermore, the electrical system can include other types of conductors (apart from electrical wires and overhead power lines) and electrical components (apart from surge voltage arrestors), and any numbers of conductors, parasitic capacitances, and surge voltage arrestors.

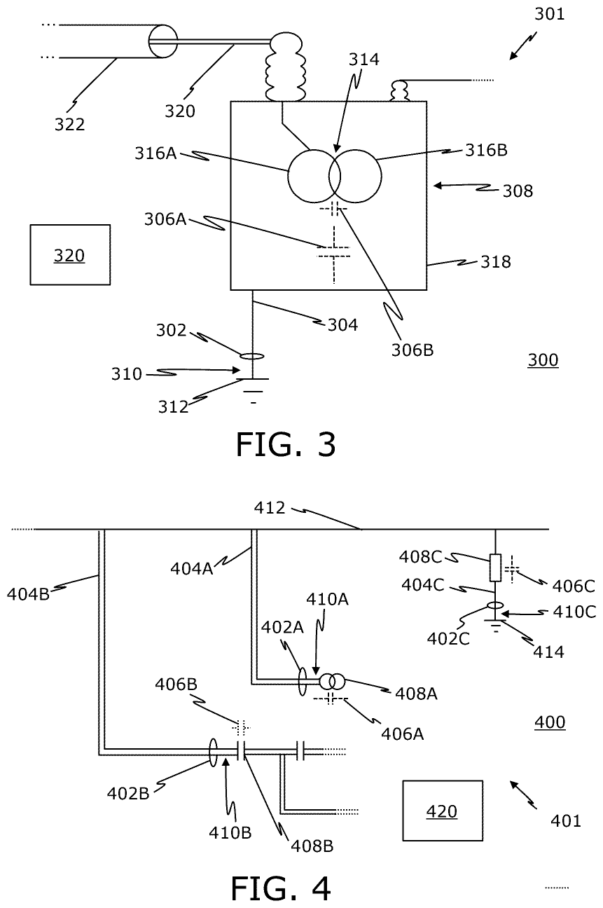

Referring to FIG. 3, there is illustrated an exemplary arrangement for detecting traveling waves by leveraging stray capacitances associated with a transformer included in an electrical system 300, in accordance with an embodiment of the present disclosure. The electrical system 300 includes a conductor 304, e.g., a ground wire. The electrical system 300 also includes a transformer 308 (an electrical component). The transformer 308 includes the first parasitic capacitance 306A and the second parasitic capacitance 306B. The arrangement 301 for detecting traveling waves comprises a current detection sensor 302, wherein the current detection sensor is associated with the conductor 304, and a processor 320, wherein the processor is associated with the current detection sensor. The association of the current detection sensor 302 with the conductor 304 may be arranged based on wrapping of the current detection sensor 302 around an ending terminal 310 of the conductor 304. The conductor 304 connects the transformer 308 with a ground terminal 312 of the electrical system 300. The association of the conductor 304 with the first parasitic capacitance 306A and the second parasitic capacitance 306B is based on the connection of the conductor 304 with the transformer 308.

The transformer 308 may include a high-voltage section and a low-voltage section. The transformer 308 includes a core 314 and a pair of windings, viz., a primary winding 316A and a secondary winding 316B. The primary winding 316A is associated with the high-voltage section and the secondary winding 316B is associated with the low-voltage section. The transformer 308 is housed in a container 318. The core 314 and the container 318 of the transformer 308 may be connected to each other by the first parasitic capacitance 306A. The pair of windings (i.e., the primary winding 316A and the secondary winding 316B) of the transformer 308 may be connected to each other by the second parasitic capacitance 306B.

The current detection sensor 302 measures stray current flowing through the conductor 304. The flow of the stray current may be due to propagation of a traveling wave through a conductor 320 enclosed by an electric shield 322. The first parasitic capacitance 306A and the second parasitic capacitance 306B of the transformer 308 provide a low-impedance path for the stray current to flow from the conductor 320 to the ground terminal 312 via the conductor 304 (i.e., the transformer 308). Based on the measurement of the stray current by the current detection sensor 302, a presence of the traveling wave in the conductor 320 and the conductor 304 (and the transformer 308) is detected.

FIG. 3 is merely an example, which should not unduly limit the scope of the claims herein. A person skilled in the art will recognize many variations, alternatives, and modifications of embodiments of the present disclosure. For example, the arrangement can include any number of current detection sensors. Furthermore, the electrical system can include other types of conductors (apart from electrical wires and power lines) and electrical components (apart from transformers), and any number of conductors, transformers, and parasitic capacitances.

Referring to FIG. 4, there is illustrated an exemplary arrangement for detecting traveling waves by leveraging stray capacitances associated with cable taps from a power line included in an electrical system 400, in accordance with an embodiment of the present disclosure. The electrical system 400 includes a first conductor 404A (a cable), a second conductor 404B (a cable), and a third conductor 404C (an electrical wire), e.g., a ground wire. The arrangement 401 for detecting traveling waves in the electrical system 400 comprises a first current detection sensor 402A, a second current detection sensor 402B, a third current detection sensor 402C, and a processor 420. The first conductor 404A is associated with the first current detection sensor 402A and a first parasitic capacitance 406A. The second conductor 404B is associated with the second current detection sensor 402B and a second parasitic capacitance 406B. The third conductor 404C is associated with the third current detection sensor 402C and a third parasitic capacitance 406C. The electrical system 400 further includes electrical components such as a transformer 408A, a switch 408B, and a surge voltage arrestor 408C. The transformer 408A includes the first parasitic capacitance 406A. The switch 408B includes the second parasitic capacitance 406B. The surge voltage arrestor 408C includes the third parasitic capacitance 406C.

The association of the first current detection sensor 402A with the first conductor 404A is arranged based on wrapping of the first current detection sensor 402A around a first ending terminal 410A of the first conductor 404A. The association of the second current detection sensor 402B with the second conductor 404B is arranged based on wrapping of the second current detection sensor 402B around a second ending terminal 410B of the second conductor 404B. The association of the third current detection sensor 402C with the third conductor 404C is arranged based on wrapping of the third current detection sensor 402C around a third ending terminal 410C of the third conductor 404C.

The first conductor 404A is a cable tap originating from a power line 412 that connects the power line 412 to the transformer 408A. The association of the first conductor 404A with the first parasitic capacitance 406A is based on the connection of the first conductor 404A with the transformer 408A. The second conductor 404B is a cable tap originating from the power line 412 that connects the power line 412 to the switch 408B. The association of the second conductor 404B with the second parasitic capacitance 406B is based on the connection of the second conductor 404B with the switch 408B. The third conductor 404B is an electrical wire that connects the power line 412 to a ground terminal 414 of the electrical system 400 via the surge voltage arrestor 408C. The association of the third conductor 408C with the third parasitic capacitance 406C is based on connection of the third conductor 408C with the surge voltage arrestor 408C.

The first current detection sensor 402A measures stray current flowing through the first conductor 404A. The flow of the stray current may be due to propagation of a traveling wave through the power line 412. The first parasitic capacitance 406A of the transformer 408A provides a low-impedance path for the stray current to flow from the power line 412 to the transformer 408A via the first conductor 404A (the cable tap from the power line 412). Based on the measurement of the stray current by the first current detection sensor 402A, a presence of the traveling wave in the power line 412 and the first conductor 404A may be detected. The second current detection sensor 402B measures stray current flowing through the second conductor 404B. The flow of the stray current may be due to propagation of the traveling wave through the power line 412. The second parasitic capacitance 406B of the switch 408B provides a low-impedance path for the stray current to flow from the power line 412 to the switch 408B via the second conductor 404B (the cable tap from the power line 412). Based on the measurement of the stray current by the second current detection sensor 402B, a presence of the traveling wave in the power line 412 and the second conductor 404B is detected.

The third current detection sensor 402C measures stray current flowing through the third conductor 404C. The flow of the stray current may be due to propagation of a traveling wave through the power line 412. The third parasitic capacitance 406C of the surge voltage arrestor 408C provides a low-impedance path for the stray current to flow from the power line 412 to the ground terminal 414 via the third conductor 404C (i.e., the surge voltage arrestor 408C). Based on the measurement of the stray current by the third current detection sensor 402C, a presence of the traveling wave in the power line 412 and the conductor 204 (and the surge voltage arrestor 408C) is detected.

FIG. 4 is merely an example, which should not unduly limit the scope of the claims herein. A person skilled in the art will recognize many variations, alternatives, and modifications of embodiments of the present disclosure. For example, the electrical system can include any number of transformers, switches, surge voltage arrestors, conductors, and parasitic capacitances. Furthermore, the electrical system can include other types of conductors (apart from cables, electrical wires, and power lines) and electrical components (apart from transformers, switches, and surge voltage arrestors). Furthermore, the arrangement can comprise any number of current detection sensors, and processors.

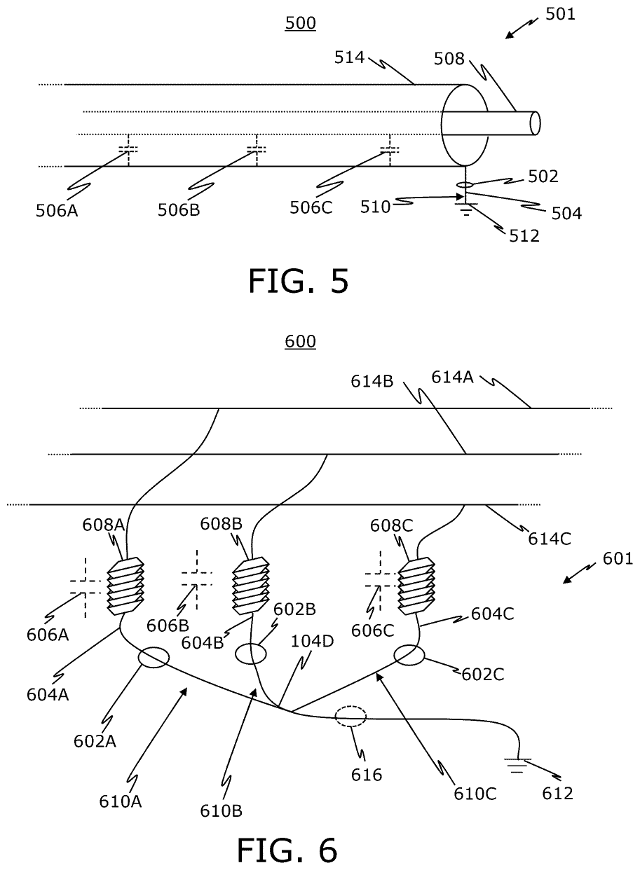

Referring to FIG. 5, there is illustrated an exemplary arrangement for detecting traveling waves by leveraging stray capacitances associated with an underground cable included in an electrical system 500, in accordance with an embodiment of the present disclosure. The arrangement 501 for detecting traveling waves in the electrical system 500 comprises a current detection sensor 502 and a processor (not shown in FIG. 5) associated with the current detection sensor 502. The electrical system 500 includes a conductor 504 (an electrical wire), e.g., a ground wire. The conductor 504 is associated with the current detection sensor 502 and a set of parasitic capacitances 506A-506C. The electrical system 500 further includes an underground cable 508 (an electrical component). The association of the current detection sensor 502 with the conductor 504 may be arranged based on wrapping of the current detection sensor 502 around an ending terminal 510 of the conductor 504. The conductor 504 may connect the underground cable 508 with a ground terminal 512 of the electrical system 500 via a metallic shield 514. The underground cable 508 may be enclosed by the metallic shield 514. The underground cable 508 and the metallic shield 514 are connected by the set of parasitic capacitances 506A-506C. The conductor 504 connects the underground cable 508 with the ground terminal 512 via the set of parasitic capacitances 506A-506C and the metallic shield. The association of the conductor 504 with the set of parasitic capacitances 506A-506C is based on the connection of the conductor 504 with the underground cable 508 via the set of parasitic capacitances 506A-506C and the metallic shield 514.

The current detection sensor 502 measures stray current flowing through the conductor 504. The flow of the stray current is due to propagation of a traveling wave through the underground cable 508 enclosed by the metallic shield 514. The set of parasitic capacitances 506A-506C provide a set of low-impedance paths for the stray current to flow from the underground cable 508 to the metallic shield 514. Subsequently, the stray current flows to the ground terminal 512 via the conductor 504. Based on the measurement of the stray current by the current detection sensor 502, a presence of the traveling wave in the underground cable 508 and the conductor 504 is detected.

FIG. 5 is merely an example, which should not unduly limit the scope of the claims herein. A person skilled in the art will recognize many variations, alternatives, and modifications of embodiments of the present disclosure. For example, the electrical system can include any number of conductors, parasitic capacitances, and underground cables. Furthermore, the electrical system can include other types of conductors (apart from electrical wire) and electrical components (apart from underground cables). Furthermore, the arrangement can comprise any number of current detection sensors, and processors.

Referring to FIG. 6, there is illustrated an exemplary arrangement for detecting traveling waves by leveraging stray capacitances associated with a set of surge voltage arrestors included in an electrical system 600, in accordance with an embodiment of the present disclosure. The arrangement 601 for detecting traveling waves in the electrical system 600 comprises a set of current detection sensors 602A-602C and a processor (not shown in FIG. 6) wherein the processor is associated with the set of current detection sensors. The electrical system 600 includes a set of conductors 604A-604C (a set of electrical wires), e.g., a set of ground wires. The set of conductors 604A-604C are associated with the set of current detection sensors 602A-602C and a set of parasitic capacitances 606A-606C. The electrical system 600 further includes a set of surge voltage arrestors 608A-608C (a set of electrical components). The association of the set of current detection sensors 602A-602C with the set of conductors 604A-604C may be arranged based on wrapping the set of current detection sensors 602A-602C around a set of ending terminals 610A-610C of the set of conductors 604A-604C. The set of conductors 604A-604C connect the set of surge voltage arrestors 608A-608C with a ground terminal 612. The set of surge voltage arrestors 608A-608C include the set of parasitic capacitances 606A-606C. The association of the set of conductors 604A-604C with the set of parasitic capacitances 606A-606C is based on the connection of the set of conductors 604A-604C with the set of surge voltage arrestors 608A-608C.

The set of current detection sensors 602A-602C measure stray currents flowing through the set of conductors 604A-604C. The flows of the stray currents may be due to propagation of traveling waves through a set of overhead power lines 614A-614C. The set of parasitic capacitances 606A-606C of the set of surge voltage arrestors 608A-608C provide a set of low-impedance paths for the high frequency stray currents to flow from the set of overhead power lines 614A-614C to the ground terminal 612 via the set of conductors 604A-604C (and the set of surge voltage arrestors 608A-608C). Based on the measurement of the stray currents by the set of current detection sensors 602A-602C, a presence of the traveling waves in the set of overhead power lines 614A-614C and the set of conductors 604A-604C is detected.

In an embodiment, a summation of the stray currents along the set of conductors 604A-604C may be computed mathematically, summed up by series connection of the current detection sensors 602A-602C, or measured directly by a single current detection sensor 616 as shown in FIG. 6. Optionally, the summation of the stray currents along the set of conductors 604A-604C may be carried out by both: the current detection sensors 602A-602C, and the single current detection sensor 616. The advantage of using a single current detection sensor is that it complements the detection of stray currents in various electrical systems.

In an embodiment, only one or two of the set of current detection sensors 602A-602C may be installed, resulting in less strong but still adequate traveling wave signal pickup.

In an embodiment, there might be several ground terminal points, in addition to 612 (see FIG. 6), in which case equipping one or more of these ground terminal points with current detection sensors 616 will provide traveling wave signal pickup.

FIG. 6 is merely an example, which should not unduly limit the scope of the claims herein. A person skilled in the art will recognize many variations, alternatives, and modifications of embodiments of the present disclosure. For example, the electrical system can include any number of conductors, parasitic capacitances, and surge voltage arrestors. Furthermore, the electrical system can include other types of conductors (apart from electrical wires and overhead power lines) and electrical components (apart from surge voltage arrestors). Furthermore, the arrangement can comprise any number of current detection sensors, and processors.

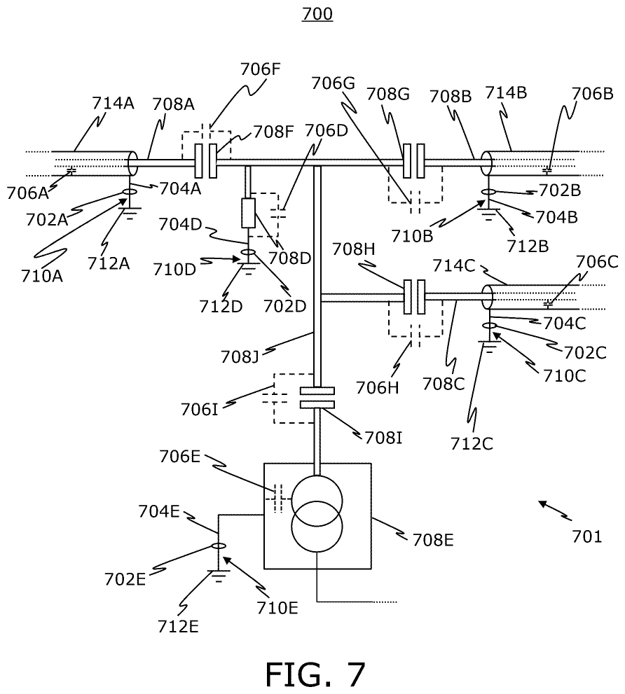

Referring to FIG. 7, there is illustrated an exemplary arrangement for detecting traveling waves by leveraging stray capacitances associated with overhead power lines, switches, a surge voltage arrestor, and a transformer included in an electrical system 700, in accordance with an embodiment of the present disclosure. The arrangement 701 for detecting traveling waves in the electrical system 700 comprises a set of current detection sensors 702A-702E and a processor (not shown in FIG. 7) wherein the processor is associated with the set of current detection sensors. The electrical system 700 includes a set of conductors 704A-704E (a set of electrical wires), e.g., a set of ground wires. The set of conductors 704A-704E are associated with the set of current detection sensors 702A-702E and a set of parasitic capacitances 706A-706E. The electrical system 700 further includes a set of electrical components. The set of electrical components include a set of overhead power lines 708A-708C, a surge voltage arrestor 708D, a transformer 708E, a set of switches 708F-7081, and another overhead power line 708J. Each overhead power line of the set of overhead power lines 708A-708C and the overhead power line 708J includes two segments. The association of the set of current detection sensors 702A-702E with the set of conductors 704A-704E may be arranged based on wrapping of the set of current detection sensors 702A-702E around a set of ending terminals 710A-710E of the set of conductors 704A-704E.

A subset of conductors 704A-704C of the set of conductors 704A-704E may connect the set of overhead power lines 708A-708C with a set of ground terminals 712A-712C of the electrical system 700 via a set of electric shields 714A-714C. The set of overhead power lines 708A-708C may be enclosed by a set of electric shields 714A-714C. The overhead power line 708A and the electric sheet 714A are connected by the parasitic capacitance 706A. The overhead power line 708B and the electric sheet 714B are connected by the parasitic capacitance 706B. The overhead power line 708C and the electric sheet 714C are connected by the parasitic capacitance 706C. The subset of conductors 704A-704C connect the set of overhead power lines 708A-708C with the set of ground terminals 712A-712C via a subset of parasitic capacitances 706A-706C of the set of parasitic capacitances 706A-706E and the set of electric shields 714A-714C. The association of the subset of conductors 704A-704C with the subset of parasitic capacitances 706A-706C is based on the connections of the subset of conductors 704A-704C with the set of overhead power lines 708A-708C via the subset of parasitic capacitances 706A-706C and the set of electric shields 714A-714C.

Furthermore, the conductor 704D connects the surge voltage arrestor 708D with a ground terminal 712D of the electrical system 700. The association of the conductor 704D with the parasitic capacitance 706D may be based on the connection of the conductor 704D with the surge voltage arrestor 708D. This is because the surge voltage arrestor 708D includes the parasitic capacitance 706D. The conductor 704E connects the transformer 708E with a ground terminal 712E of the electrical system 700. The association of the conductor 704E with the parasitic capacitance 706E may be based on the connection of the conductor 704E with the transformer 704E. This is because the transformer 708E includes the parasitic capacitance 706E.

The terminals of the switch 708F connect the segments of the overhead power line 708A when the switch 708F is in open state. The terminals of the switch 708G connect the segments of the overhead power line 708B when the switch 708G is in open state. The terminals of the switch 708H connect the segments of the overhead power line 708C when the switch 708H is in open state. The terminals of the switch 708I connect two segments of the overhead power line 708J when the switch 708I is in open state. The set of overhead power lines 708A-708C may be associated with a set of parasitic capacitances 706F-706H and the overhead power line 708J may be associated with a parasitic capacitance 706I. Each switch of the set of switches 708F-708I includes two terminals. A subset of parasitic capacitances 706F-706H of the set of parasitic capacitances 706F-706I provide a set of low-impedance paths for the stray currents to flow through the set of overhead power lines 708A-708C. Furthermore, the parasitic capacitance 706I provides a low-impedance path for stray current to flow through the overhead power line 708J.

A subset of current detection sensors 702A-702C of the set of current detection sensors 702A-702E measure stray currents flowing through the subset of conductors 704A-704C. The flows of the stray currents are due to propagation of traveling waves through the set of overhead power lines 708A-708C. The subset of parasitic capacitances 706A-706C provide a set of low-impedance paths for the stray currents to flow from the set of overhead power lines 708A-708C to the set of electric shields 714A-714C. Subsequently, the stray currents flow to the set of ground terminals 712A-712C via the subset of conductors 704A-704C. Based on the measurements of the stray currents by the subset of current detection sensors 702A-702C, presence of the traveling waves in the set of overhead power lines 708A-708C and the subset of conductors 704A-704C is detected.

The current detection sensor 702D measures stray current flowing through the conductor 704D. The flow of the stray current may be due to the propagation of the traveling wave through the overhead power line 708A. The parasitic capacitance 706D of the surge voltage arrestor 708D and the parasitic capacitance 706F of the switch 708F provide a low-impedance path for the stray current to flow from the overhead power line 708A to the ground terminal 712D via the conductor 704D (and the surge voltage arrestor 708D). Based on the measurement of the stray current by the current detection sensor 702D, a presence of the traveling wave in the overhead power line 708A and the conductor 704D is detected.

The current detection sensor 702E measures stray current flowing through the conductor 704E. The flow of the stray current may be due to propagation of a traveling wave through the overhead power line 708J. The parasitic capacitance 706E of the transformer 708E and the parasitic capacitance 706I of the switch 708I provide a low-impedance path for the stray current to flow from the overhead power line 708J to the ground terminal 712E via the conductor 704E (and the transformer 708E). Based on the measurement of the stray current by the current detection sensor 702E, a presence of the traveling wave in the overhead power line 708J and the conductor 704E is detected.

FIG. 7 is merely an example, which should not unduly limit the scope of the claims herein. A person skilled in the art will recognize many variations, alternatives, and modifications of embodiments of the present disclosure. For example, the electrical system can include any number of conductors, parasitic capacitances, and electrical components. Furthermore, the arrangement can comprise any number of current detection sensors, and processors.

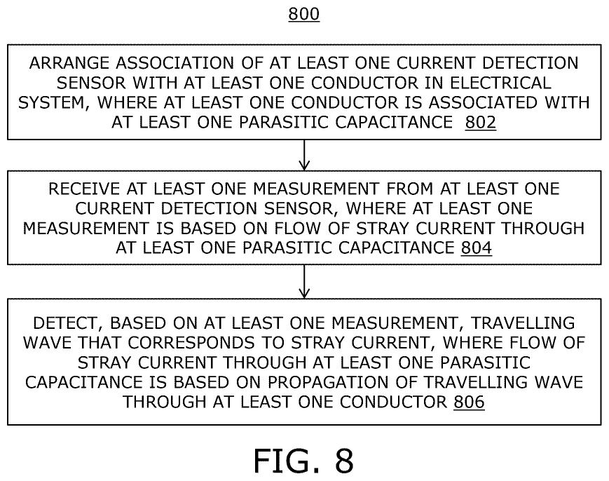

Referring to FIG. 8, depicted are steps of a method 800 for detecting high-frequency traveling waves by use of current sensors in electrical systems 100-700, in accordance with an embodiment of the present disclosure. At step 802, association of at least one current detection sensor 102A, 102B, 202, 302, 402A-402C, 502, 602A-602C, and 702A-702E with at least one conductor 104, 204, 304, 404A-404C, 504, 604A-604C, and 704A-704E in the electrical system 100-700.

The at least one conductor 104, 204, 304, 404A-404C, 504, 604A-604C, and 704A-704E is associated with at least one parasitic capacitance 106, 206, 306A, 306B, 406A-406C, 506A-506C, 606A-606C, and 706A-706I. At step 804, at least one measurement is received from the at least one current detection sensor 102A, 102B, 202, 302, 402A-402C, 502, 602A-602C, and 702A-702E. The at least one measurement is based on flow of stray current through the at least one parasitic capacitance 106, 206, 306A, 306B, 406A-406C, 506A-506C, 606A-606C, and 706A-706I. At step 806, a traveling wave, corresponding to the stray current, is detected based on the at least one measurement. The flow of the stray current through the at least one parasitic capacitance 106, 206, 306A, 306B, 406A-406C, 506A-506C, 606A-606C, and 706A-706I is based on propagation of the traveling wave through the at least one conductor 104, 204, 304, 404A-404C, 504, 604A-604C, and 704A-704E.

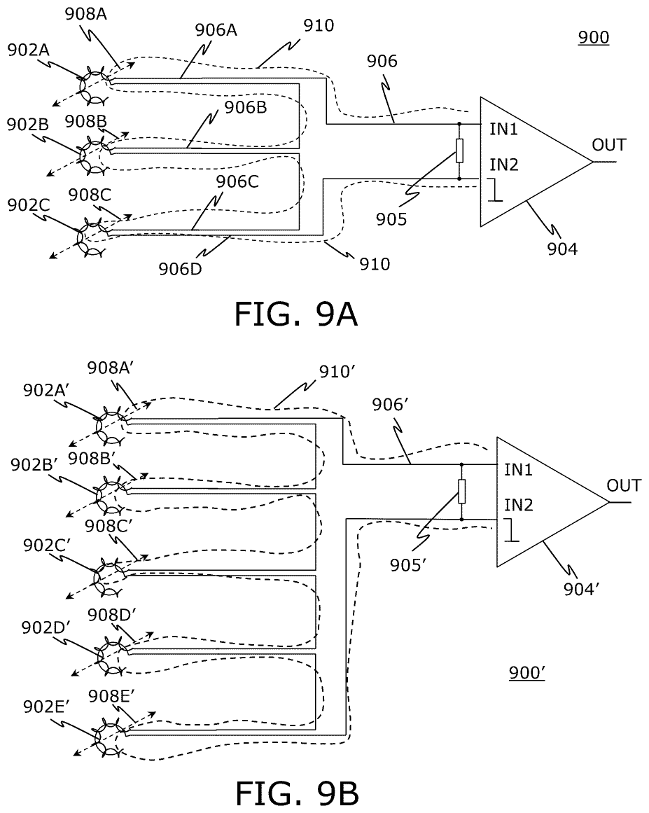

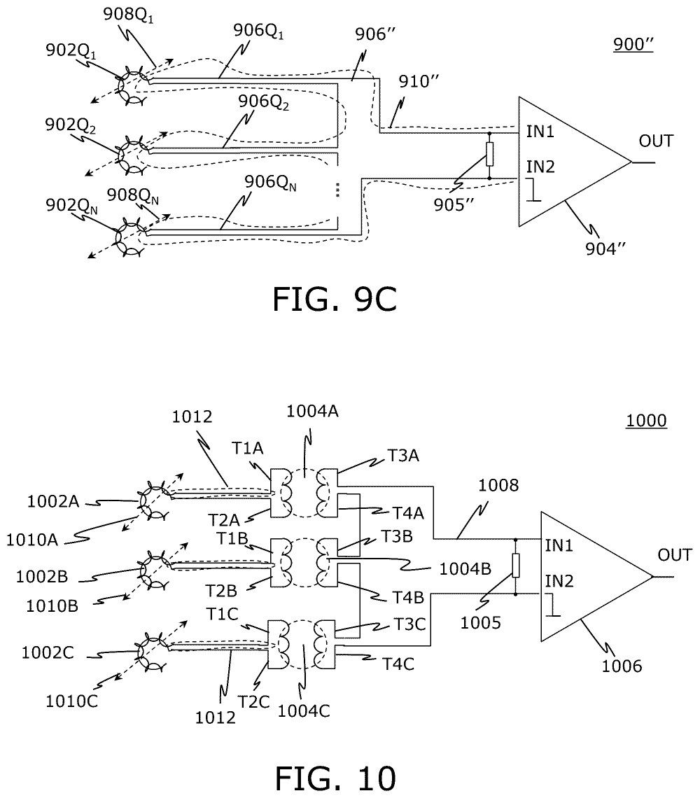

Referring to FIG. 9A, there is illustrated an exemplary arrangement for detecting traveling waves from ground wires (i.e., a set of conductors) produced by, e.g. the stray capacitances at a secondary substation or at surge voltage arrestors according to the present disclosure, by the use of a set of Rogowski coils or current transformers included in an electrical system, in accordance with an embodiment of the present disclosure. Each of the ground wires may be associated with at least one parasitic capacitance.

The arrangement 900, in FIG. 9A, includes three current detection sensors, for example, three Rogowski coil or current transformers, comprising a first current detection sensor 902A, a second current detection sensor 902B, and a third current detection sensor 902C. The arrangement 900 further comprises an amplifier 904 having at least two (input) terminals: a first terminal IN1, and a second terminal IN2, and an output OUT (see FIG. 9A), wherein the amplifier is configured to be connected to a traveling wave detection circuitry, through the output OUT, to detect traveling wave signals when the arrangement 900 is used. Alternatively, the amplifier 904 may also be a first amplifier stage (that might include filters also) of the traveling wave detection circuitry. The amplifier comprises, for example, a differential amplifier followed by a possible integrator, an analog-to-digital converter, microprocessor, and/or FPGA. The traveling wave detection circuitry may additionally include a plurality of electrical components, such as passive and/or active components and software. The arrangement 900 further comprises a conductor 906 which connects the three Rogowski coils or current transformers 902A-902C in series.

Referring further to FIG. 9A, each current detection sensor has a first end and a second end, wherein the first current detection sensor 902A has the first end connected to the first terminal (IN1) of the amplifier 904 through a section 906A of the conductor 906, and the second end connected to the first end of the second current detection sensor 902B through the section 906B of the conductor 906. The second end of the second current detection sensor 902B is connected to the first end of the third current detection sensor 902C through a section 906C of the conductor 906 and the second end of the third current detection sensor 902C is connected to the second terminal (IN2) of the amplifier 904 through a section 906D of the conductor 906. The three current detection sensors 902A, 902B, and 902C are arranged to be installed in series on three ground wires, respectively, by winding the three detection sensors 902A, 902B, and 902C around the ground wires in a non-intrusive manner. The series connection of current detection sensors has the effect of summing the output voltages produced by the current detection sensors. In operation, the first current detection sensor 902A is wound around a first ground wire, the second current detection sensor 902B is wound around a second ground wire, and the third current detection sensor 902C is wound around a third ground wire (the ground wires are not shown in FIG. 9A).

The arrangement 900 further comprises a resistor 905 at the input of the amplifier 904. The resistor 905 is connected between the first terminal IN1 and the second terminal IN2 of the amplifier. When using a current transformer (CT) or a Rogowski coil as a sensor, it's common practice to place a short-circuiting resistor (also called a burden resistor) before the first amplifier stage. This resistor plays a crucial role in the signal conditioning and safety of the system, as in an open-circuit condition, a CT can generate dangerously high voltages, which can be hazardous to both equipment and personnel. Rogowski coils are designed to measure AC currents, and their output is proportional to the time derivative of the current. The resistor helps in shaping the frequency response of the sensor.

Each of the current detection sensors is capable of measuring current 908A, 908B, 908C flowing through a ground wire around which the Rogowski coil or current transformer is wrapped. The current detection sensor 902A may be capable of measuring current 908A, the current detection sensor 902B may be capable of measuring current 908B, and the current detection sensor 902C may be capable of measuring current 908C. The currents 908A-C may correspond to high-frequency traveling wave signals propagating through the ground wires. As the current detection sensors 902A-C are connected to the amplifier 904, the amplifier is then operable to detect a high-frequency traveling wave signal propagating through the electrical system 900, or for the purposes of this invention, through various ground wires, in order to pick up traveling wave signals from those wires based on the flow of the currents 908A-C.

As in the example of FIG. 7, it is clear that in the secondary substation, there might be a need to add several Rogowski coils or current transformers, for example, as many Rogowski coils or current transformers as there are ground wires in the electrical system.

FIG. 9B illustrates another exemplary arrangement for detecting traveling waves in an electrical system. The exemplary arrangement 900′, in FIG. 9B, includes five current detection sensors, comprising a first current detection sensor 902A′, a second current detection sensor 902B′, a third current detection sensor 902C′, a fourth current detection sensor 902D′, and a fifth current detection sensor 902E′. The first current detection sensor 902A′ is configured to measure current 908A′ flowing in the conductor (not shown in FIG. 9B) passing through the coil of the current detection sensor 902A′, the second current detection sensor 902B′ is configured to measure current 908B′ flowing in the conductor (not shown in FIG. 9B) passing through the coil of the current detection sensor 902B′, the third current detection sensor 902C′ is configured to measure current 908C′ flowing in the conductor (not shown in FIG. 9B) passing through the coil of the current detection sensor 902C′, the fourth current detection sensor 902D′ is configured to measure current 908D′ flowing in the conductor (not shown in FIG. 9B) passing through the coil of the current detection sensor 902D′, and the fifth current detection sensor 902E′ is configured to measure current 908E′ flowing in the conductor (not shown in FIG. 9B) passing through the coil of the current detection sensor 902E′. The arrangement 900′ further comprises an amplifier 904′ associated with the current detection sensors 902A′-902E′ arranged in series through a conductor 906′, and a resistor 905′ arranged between a first terminal IN1 and a second terminal IN2 of the amplifier, at the input of the amplifier 904′. Each of the conductors passing through the coils of the current detection sensors may be ground wires. In addition, each of the ground wires may be associated with at least one parasitic capacitance.

Referring to FIG. 9C, illustrated is yet another exemplary arrangement 900″ for detecting traveling waves in the electrical system. The arrangement of FIG. 9C comprises N current detection sensors 902Q₁, 902Q₂, . . . , 902Q_{N} arranged in series, wherein N is any natural number N=(1, 2, 3, . . . ), wherein each of the current detection sensors is wrapped around one ground wire, wherein each one ground wire is corresponding to each one current detection sensor, and wherein each of the current detection sensors is configured to measure current 908Q₁, . . . , 908Q_{N} flowing through the corresponding ground wire. The arrangement 900″ further comprises an amplifier 904′ associated with the current detection sensors 902Q₁, 902Q₂, . . . , 902Q_{N} arranged in series through a conductor 906′, and a resistor 905″ at the input of the amplifier 904′. Each of the ground wires may be associated with at least one parasitic capacitance, or at least one stray capacitance.

The series connection of multiple current detection sensors (Rogowski coils or current transformers), being a common method for summing up the measured line currents, however, may lead to creation of a large and unbalanced antenna structure which makes the conductors 906, 906′, 906″ prone to harmful Radio Frequency (RF) interferences 910, 910′, 910″ (indicated by dashed lines in FIGS. 9A, 9B and 9C) and therefore disturbing the high-frequency traveling wave signal detection. Each of the sections in the conductor 906 (906A-906D) may individually contribute to RF interference detection by the amplifier 904). Furthermore, individual sections (906A/906B/906C/906D) of the conductor 906 and distances between each pair of sections, such as first section 906A and the second section 906B, or the second section 906B and the third section 906C, transfer common-mode RF interference into differential mode, which may be measured by the amplifier 904 and correspondingly detected by a traveling wave detection circuitry.

FIGS. 9A, 9B and 9C are merely examples, which should not unduly limit the scope of the claims herein. A person skilled in the art will recognize many variations, alternatives, and modifications of embodiments of the present disclosure. For example, each of the arrangements shown in FIGS. 9A, 9B and 9C may comprise any number of current detection sensors, coils, conductors, and electrical components, and one or more processors.

Referring to FIG. 10, there is illustrated an exemplary arrangement for detecting traveling waves using Rogowski coils or current transformers (i.e., current detection sensors) included in an electrical system, in accordance with an embodiment of the present disclosure. The arrangement 1000 comprises three Rogowski coils or current transformers 1002A-1002C, three RF balun transformers 1004A-1004C (high-frequency transformers), and an amplifier 1006 for example, a differential amplifier. The arrangement 1000 may further comprises a processor.

Referring to FIG. 10, the first RF balun transformer 1004A has a first side with a first winding arranged between two terminals T1A and T2A, wherein the first side is arranged on side of the first Rogowski coil or current transformer 1002A, and a second side with a second winding arranged between two terminals T3A and T4A wherein the second side is arranged on side of the amplifier 1006. Additionally, the second RF balun transformer 1004B has a first side with a first winding arranged between two terminals T1B and T2B wherein the first side is arranged on side of the second Rogowski coil or current transformer 1002B, and a second side with a second winding arranged between two terminals T3B and T4B wherein the second side is arranged on side of the amplifier 1006. Additionally, the third RF balun transformer 1004C has a first side with a first winding arranged between two terminals T1C and T2C wherein the first side is arranged on side of the third Rogowski coil or current transformer 1002C, and a second side with a second winding arranged between two terminals T3C and T4C wherein the second side is arranged on side of the amplifier 1006.

Referring further to FIG. 10, the first end of the first Rogowski coil or current transformer 1002A is connected to the first terminal T1A of the RF balun transformer 1004A and the second end of the first Rogowski coil or current transformer 1002A is connected to the second terminal T2A of the first RF balun transformer 1004A. The third terminal T3A of the first RF balun transformer 1004A is connected to the first terminal (IN1) of the amplifier 1006 and the fourth terminal T4A of the first RF balun transformer 1004A is connected to the third terminal T3B of the second RF balun transformer 1004B. The first end of the second

Rogowski coil or current transformer 1002B is connected to the first terminal T1B of the second RF balun transformer 1004B and the second end of the second Rogowski coil or current transformer 1002B is connected to the second terminal T2B of the second RF balun transformer 1004B. The fourth terminal T4B of the second RF balun transformer 1004B is connected to the third terminal T3C of the third RF balun transformer 1004C. The first end of the third Rogowski coil or current transformer 1002C is connected to the first terminal T1C of the third RF balun transformer 1004C and the second end of the third Rogowski coil or current transformer 1002C is connected to the second terminal T2C of the third RF balun transformer 1004C. The fourth terminal T4C of the third RF balun transformer 1004C is further connected to the second terminal (IN2) of the amplifier 1006.

The three Rogowski coils or current transformers 1002A-1002C are connected in series by a conductor 1008. The arrangement 1000 further comprises a resistor 1005 which is arranged at the input of the amplifier 1006, between the first terminal and the second terminal of the amplifier 1006. In operation, a voltage drop across the resistor 1005 is associated with the derivative of the current detected by the first Rogowski coil or the current detected by the first current transformer.

Each Rogowski coil or current transformer 1002A/1002B/1002C is capable of measuring current 1010 flowing through the conductor, as an example a ground wire, around which the Rogowski coil or current transformer is wrapped. The Rogowski coil or current transformer 1002A is capable of measuring the current 1010A, the Rogowski coil or current transformer 1002B is capable of measuring the current 1010B, and the Rogowski coil or current transformer 1002C is capable of measuring the current 1010C. The current 1010A, 1010B, 1010C may correspond to a high-frequency traveling wave signal propagating along the conductor 1008. The output of the amplifier 1006 is configured to be connected to a traveling wave detection circuitry to detect a high-frequency traveling wave (signal) and/or it may function as a traveling wave detector that is operable to accurately detect a high-frequency traveling wave propagating through the electrical system 1000 based on the flow of the current through the conductor 1008 to the amplifier 1006. In operation, current 1010A-1010C is measured with the Rogowski coils or current transformers 1002A-C, which produce a voltage that can be utilized for detecting the traveling wave signal 1010A-C traveling through the Rogowski coils or current transformer (primary) windings.

If comparing the arrangements illustrated in FIGS. 9A, 9B and 9C to the arrangement in the embodiment illustrated in FIG. 10, an advantage of the embodiment of FIG. 10 is that the three RF balun transformers 1004A-1004C will significantly reduce the size of the antenna structure that would otherwise be formed by the series connection of the three Rogowski coils or current transformers 1002A-1002C, as the common mode RF signal path is cut at the RF balun transformers 1004A-1004C. The antenna structure increases probability of RF interference 1012 at frequencies that are close to the high-frequency traveling waves (which are to be detected). The sources of the RF interference 1012 may be a switch mode equipment on lower voltage power lines of the electrical system 1000, and other equipment in the electrical system 1000 such as motor controllers, active reactors, inverters, switch-mode power supplies, radio transmitters, and so on. The RF interference 1012 at the conductor 1008 significantly reduces accuracy of a detected traveling wave propagating through the Rogowski coils or current transformers 1002A-C. The three RF balun transformers 1004A-1004C may prevent the formation of the antenna structure and, thereby, facilitate in countering common mode RF interference (such as the RF interference 1012). The inclusion of the three RF balun transformers 1004A-1004C between the pickup sensors (Rogowski coils or current transformers in this example) and the first amplifier stage of the traveling wave detection system convert the series connection of the three Rogowski coils or current transformers 1002A-1002C into three isolated Rogowski coil/current transformer-RF balun transformer connections (i.e., eliminating any induced common mode voltages). This significantly minimizes the RF interference 1012 at the first amplifier stages 1006 of the traveling wave pickup system. The RF interference 1012 may be further reduced by usage of anti-interference cabling.

FIG. 10 is merely an example, which should not unduly limit the scope of the claims herein. A person skilled in the art will recognize many variations, alternatives, and modifications of embodiments of the present disclosure. For example, the arrangement 1000 can include any number of Rogowski coils or current transformers, any number of RF balun transformers, and any number of processors.

The aforementioned steps are only illustrative and other alternatives can also be provided where one or more steps are added, one or more steps are removed, or one or more steps are provided in a different sequence without departing from the scope of the claims herein.

1. A method for detecting traveling waves in an electrical system, the method comprising:
arranging association of at least one current detection sensor with at least one conductor in the electrical system, wherein the at least one conductor is associated with at least one parasitic capacitance;
receiving at least one measurement from the at least one current detection sensor, wherein the at least one measurement is based on flow of stray current through the at least one parasitic capacitance; and
detecting, based on the at least one measurement, a traveling wave that corresponds to the stray current, wherein the flow of the stray current through the at least one parasitic capacitance is based on propagation of the traveling wave through the at least one conductor.

2. The method according to claim 1, wherein the electrical system is a primary substation or a secondary substation, wherein the electrical system includes a set of electrical components, wherein the set of electrical components include one or more of: at least one switch, at least one surge voltage arrestor, at least one transformer, at least one underground cable, and at least one overhead power line.

3. The method according to claim 1, wherein the at least one current detection sensor is associated with the at least one conductor by wrapping the at least one current detection sensor around at least one ending terminal of an at least one electric shield, and wherein the at least one electric shield encloses the at least one conductor.

4. The method according to claim 2, wherein the at least one switch connects a set of segments of the at least one conductor, and wherein terminals of the at least one switch are connected by the at least one parasitic capacitance when the at least one switch is in open state.

5. The method according to claim 2, wherein the at least one current detection sensor is associated with the at least one conductor by wrapping the at least one current detection sensor around at least one ending terminal of the at least one conductor, wherein the at least one conductor connects at least one electrical component of the set of electrical components with at least one ground terminal in the electric system, and wherein the at least one electrical component corresponds to one or more of the at least one the surge voltage arrestor or the at least one transformer.

6. The method according to claim 5, wherein the at least one surge voltage arrestor includes the at least one parasitic capacitance.

7. The method according to claim 5, wherein the at least one transformer includes a core and a pair of windings, wherein the at least one transformer is housed in at least one container, wherein the pair of windings of the at least one transformer are connected by the at least one parasitic capacitance, and wherein the core and the container of the at least one transformer are connected by the at least one parasitic capacitance.

8. The method according to claim 7, wherein the method further comprises preventing flow of an electric current from a secondary winding of the at least one transformer to the at least one conductor via the at least one parasitic capacitance, wherein the pair of windings include a primary winding and the secondary winding.

9. The method according to claim 2, wherein the at least one current detection sensor is associated with the at least one conductor by wrapping the at least one current detection sensor around at least one ending terminal of the at least one conductor, wherein the at least one conductor connects a power line with one or more of the at least one transformer and the at least one switch, wherein the at least one parasitic capacitance is included in the at least one transformer and the at least one switch.

10. The method according to claim 9, wherein the method further comprises enhancing a current signal for generating an enhanced current signal, wherein the enhanced current signal corresponds to the stray current, and wherein an amplitude of the stray current is greater than or equal to a threshold amplitude that is detectable by the at least one detection sensor.

11. The method according to claim 10, wherein the current signal is enhanced based on an arrangement causing a superposition of an electric current flowing through the power line and the current signal.

12. The method according to claim 2, wherein the at least one current detection sensor is associated with the at least one conductor by wrapping the at least one current detection sensor around at least one ending terminal of the at least one conductor, and wherein the at least one conductor connects the at least one underground cable with at least one ground terminal of the electric system via at least one metallic shield enclosing the at least one underground cable.

13. The method according to claim 12, wherein the at least one underground cable and the at least one metallic shield are connected by the at least one parasitic capacitance.

14. The method according to claim 2, wherein the at least one current detection sensor is associated with the at least one conductor by wrapping the at least one current detection sensor around at least one ending terminal of the at least one conductor, and wherein the at least one conductor connects the at least one overhead power line with at least one ground terminal of the electric system via at least one an electric shield enclosing the at least one overhead power line.

15. The method according to claim 14, wherein the at least one overhead power line and the at least one electric shield are connected by the at least one parasitic capacitance.

16. The method according to claim 2, wherein the at least one switch connects a set of segments of the at least one overhead power line, and wherein terminals of the at least one switch are connected by the at least one parasitic capacitance when the at least one switch is in open state.

17. The method according to claim 1, wherein a frequency of the traveling wave is in the range 10 kilohertz (kHz)-4 Gigahertz (GHz).

18. An arrangement for detecting traveling waves in an electrical system, the arrangement comprising:
at least one current detection sensor;
wherein the at least one current detection sensor is configured to be associated with at least one conductor, wherein the at least one conductor is associated with at least one parasitic capacitance; and
a processor, wherein the processor is operable to:
receive at least one measurement from the at least one current detection sensor, wherein the at least one measurement is based on flow of a stray current through the at least one parasitic capacitance associated with the at least one conductor, and
detect, based on the at least one measurement, a traveling wave that corresponds to the stray current, wherein the flow of the stray current through the at least one parasitic capacitance is based on propagation of the traveling wave through the at least one conductor.

19. An arrangement for detecting traveling waves in an electrical system, the arrangement comprising:
at least one Rogowski coil or current transformer;
at least one Radio Frequency (RF) balun transformer, wherein the at least one RF balun transformer is associated with the at least one Rogowski coil or current transformer;
wherein the at least one Rogowski coil or current transformer is configured to be associated with at least one conductor, wherein the at least one Rogowski coil or current transformer is operable to measure stray current flowing through the at least one conductor, and wherein the at least one RF balun transformer is configured to cancel RF interference at the at least one conductor; and
an amplifier, wherein the amplifier is connected with the at least one Radio Frequency (RF) balun transformer, and further connected to a traveling wave detection circuitry, wherein the traveling wave detection circuitry is operable to detect a traveling wave that corresponds to the stray current associated with the at least one conductor.

20. An arrangement according to claim 19, comprising a plurality of Rogowski coils or current transformers arranged in series, and a plurality of Radio Frequency (RF) balun transformers, wherein the plurality of RF balun transformers are associated with the plurality of Rogowski coils or current transformers.
